(19) United States
(12) Patent Application Publication
(10) Pub. No.: US 2019/0363077 A1
(43) Pub. Date: Nov. 28, 2019

(54) ELECTROSTATIC DISCHARGE PROTECTION CIRCUIT

(71) Applicant: GETAC TECHNOLOGY CORPORATION, Hsinchu County (TW)

(72) Inventor: SHIH-HUNG YANG, Taipei City (TW)

(21) Appl. No.: 16/144,802

(22) Filed: Sep. 27, 2018

Related U.S. Application Data
(60) Provisional application No. 62/676,863, filed on May 25, 2018.

(51) Int. Cl. H01L 27/02; H02H 9/04

(52) U.S. Cl. CPC H01L 27/0266; H01L 29/866; H02H 9/046; H01L 27/0288

(57) ABSTRACT

Embodiments of the present invention provide an electrostatic discharge protection circuit connected in series between a protection target and an external circuit. The electrostatic discharge protection circuit includes an N-type field-effect transistor and a diode. The N-type field-effect transistor has a drain coupled to an input pin of the protection target, a source coupled to a ground voltage, and a gate coupled to the external circuit. The diode has an anode coupled to the ground voltage, and a cathode together with the gate of the N-type field-effect transistor coupled to the external circuit.

### CROSS-REFERENCE TO RELATED APPLICATIONS

The present application claims the benefit of U.S. provisional Patent Application No. 62/676,863, filed on May 25, 2018, the disclosure of which is hereby incorporated by reference herein in its entirety.

### BACKGROUND OF THE INVENTION

### Field of the Invention

The present invention relates to an electrostatic discharge protection circuit connected in series between a protection target and an external circuit, and more particularly to an electrostatic discharge protection circuit capable of enhancing voltage tolerance of a protection target against electrostatic discharge.

### Description of the Prior Art

In a protection target, such as a microcontroller (MCU), when there is an input/output (I/O) pin needing to connect to an external circuit, electrostatic discharge tests are usually required. Further, a protection element such as a Zener diode or a transient voltage suppression (TVS) diode is added between the protection target and the external circuit to provide a solution for the protection target to withstand against electrostatic discharge. However, because a protection target has lower voltage tolerance against electrostatic discharge and errors among the above protection elements are quite large, appropriately selecting a suitable protection element is extremely challenging in the prior art. Moreover, the capability of a protection target for detecting whether an input/output pin is at a high level or low level can be affected.

### SUMMARY OF THE INVENTION

In view of the above, it is an object of the present invention to provide an electrostatic discharge protection circuit capable of enhancing voltage tolerance of a protection target against electrostatic discharge. To achieve the above object, an electrostatic discharge protection circuit is provided according to an embodiment of the present invention. The electrostatic discharge protection circuit is connected in series between a protection target and an external circuit, and includes an N-type field-effect transistor and a diode. The N-type field-effect transistor has a drain couple to an input pin of the protection target, a source coupled to a ground voltage and a gate coupled to the external circuit. The diode has an anode coupled to the ground voltage, and a cathode together with the gate of the N-type field-effect transistor coupled to the external circuit.

An electrostatic discharge protection circuit is further provided according to another embodiment of the present invention. The electrostatic discharge protection circuit is connected in series between a protection target and an external circuit, and includes a Schottky diode and a diode. The Schottky diode has an anode coupled to an output pin of the protection target, and a cathode coupled to the external circuit. The diode has an anode coupled to a ground voltage, and a cathode together with the cathode of the Schottky diode coupled to the external circuit.

To better understand the features and technical contents of the present invention, detailed description of the present invention is given with the accompanying drawings below. It should be noted that the description and the drawings are for explaining the present invention and are not to be construed as limitations to the scope of the present invention.

### BRIEF DESCRIPTION OF THE DRAWINGS

FIG. 1 is a circuit schematic diagram of an electrostatic discharge protection circuit according to an embodiment of the present invention; and

FIG. 2 is a circuit schematic diagram of an electrostatic discharge protection circuit according to another embodiment of the present invention.

### DETAILED DESCRIPTION OF THE EMBODIMENTS

In the disclosure below, various embodiments of the present invention are described in detail with the accompanying drawings. However, the concept of the present invention may be realized by numerous forms and are not to be construed as being limited to the non-limiting, illustrative embodiments in the disclosure. Further, the same reference numerical values in the drawings may represent similar elements.

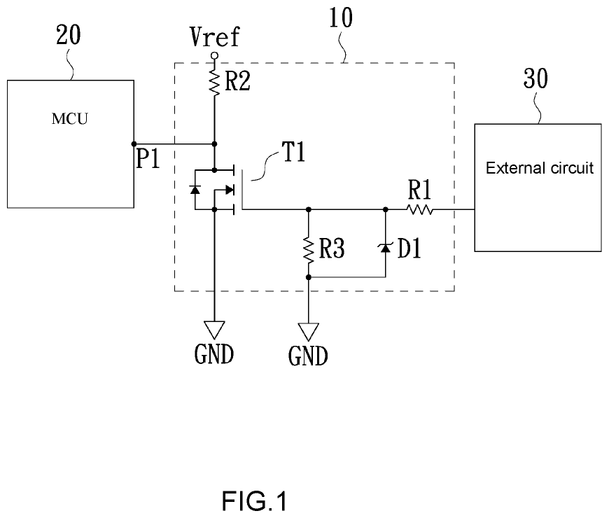

More specifically, an electrostatic discharge protection circuit provided by an embodiment of the present invention may be connected in series between any protection target and any external circuit. In brief, the present invention does not define a specific implementation form of the protection target and the external circuit, and a person skilled in the art can configure associated designs according to actual requirements or applications. For better illustration, a microcontroller (MCU) is taken as an example rather than a limitation of a protection target in the embodiments. FIG. 1 shows a circuit schematic diagram of an electrostatic discharge protection circuit provided by an embodiment of the present invention.

As shown in FIG. 1, an electrostatic discharge protection circuit 10 includes an N-type field-effect transistor T1 and a diode D1. The N-type field-effect transistor T1 has a drain coupled to the protection target, i.e., an input pin P1 of the MCU 20, a source coupled to a ground voltage GND, and a gate coupled to an external circuit 30. The diode D1 has an anode coupled to the ground voltage GND, and a cathode together with the gate of the N-type field-effect transistor T1 coupled to the external circuit 30. Further, in this embodiment, the electrostatic discharge protection circuit 10 may further include a resistor R1, and the cathode of the diode D1 and the gate of the N-type field-effect transistor are together coupled to the external circuit 30 through the resistor R1.

On the basis of teaching provided by the above disclosure, a person skilled in the art can understand that, the MCU 20 of this embodiment determines whether the external circuit 30 provides an input voltage thereof by detecting whether the voltage at the input pin P1 drops from a high level (High) to a low level (Low). Hence, in the embodiment, the input pin P1 of the MCU 20 and the drain of the N-type field-effect transistor T1 may together be coupled to a reference voltage Vref through a resistor R2, and the electrostatic discharge protection circuit 10 may further include a resistor R3 connected in parallel to the diode D1. That is to say, when the external circuit 30 does not provide an input voltage to the MCU 20, the voltage at the input pin P1 can be maintained as the reference voltage Vref at a high level through the resistors R2 and R3. The reference voltage Vref is, for example but not limited to, 3.3 V.

It should be noted that, in this embodiment, for example but not limited to, the N-type field-effect transistor T1 may be an N-type metal-oxide-semiconductor field-effect transistor (MOSFET), and the diode D1 may be a Zener diode. Thus, when an electrostatic voltage (not shown) from the external circuit 30 causes a voltage difference between the gate and the source of the N-type field-effect transistor T1 to exceed a threshold voltage of the N-type field-effect transistor T1, the N-type field-effect transistor T1 is turned on, such that the voltage at the input pin P1 also drops from a high level to a low level, thus achieving the effect of protecting the MCU 20. Moreover, since a Zener diode conventionally serving for protection purposes, i.e., the diode D1, is configured on the gate of the N-type field-effect transistor T1, the diode D1 is still capable of reducing the electrostatic voltage from the external circuit 30 during an electrostatic discharge test in this embodiment, while the specification of the diode D1 only needs to be lower than the gate withstand voltage of the N-type field-effect transistor T1. That is to say, the specification of the diode D1 can be selected and determined according to the gate withstand voltage of the N-type field-effect transistor T1. Therefore, the embodiment is capable of more appropriately selecting a suitable protection element.

As seen, one N-type metal-oxide-semiconductor field-effect transistor is added in this embodiment, i.e., the N-type field-effect transistor T1, the drain of the N-type field-effect transistor T1 is coupled to the input pion P1, the foregoing Zener diode serving for protection purposes, i.e., the diode D1, is configured to connect on the gate of the N-type field-effect transistor T1, and the gate is coupled to the external circuit 30. Thus, even if the input pin P1 of the MCU 20 can usually withstand 4 V o 6 V, compared to the prior art, the embodiment is capable of increasing the withstand voltage of originally 4 V or 6 V to 12 V, 20 V or even a higher voltage. That is to say, the voltage tolerance of the MCU 20 against electrostatic discharge is increased, which is equivalently enhancing the capability of the MCU 20 against electrostatic discharge. It should be noted that, in other embodiments, the MCU 20 may also be modified to determining whether the external circuit 30 provides thereto an input voltage by detecting whether the voltage at the input pin P1 rises from a low level to a high level. In summary, the above modification does not affect the implementation of the present invention. Associated details are as described in the foregoing disclosure, and are omitted herein.

It can be understood that, the resistor R1 acts as a current limiting resistor to prevent an overly large current from damaging the diode D1 connected in series. Thus, the specification of the diode D1 is selected and determined according to the design of the resistor R1. For example, assuming that a large electrostatic voltage is inputted from the external circuit 30, the current impact received by the diode D1 gets smaller as the ohm value of the resistor R1 increases; conversely, the current impact received by the diode D1 gets larger as the ohm value of the resistor R1 decreases. However, the operation principle of a current limiting resistor is generally known to a person skilled in the art, and details associated with the resistor R1 are omitted herein for brevity.

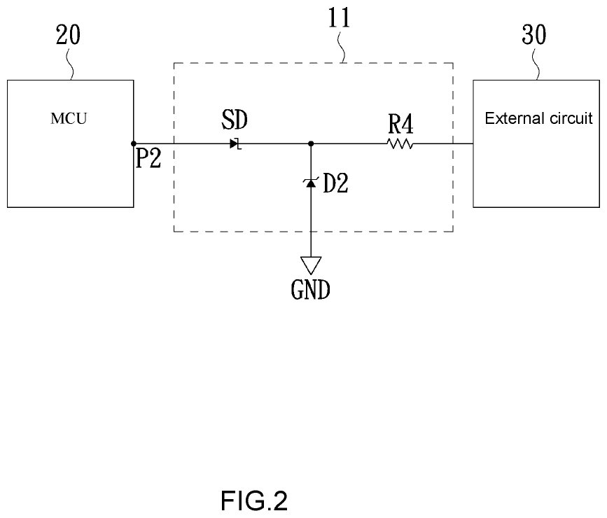

FIG. 2 shows a circuit schematic diagram of an electrostatic discharge protection circuit provided by another embodiment of the present invention. Referring to FIG. 2, some of elements in FIG. 2 same as those in FIG. 1 are represented by the same denotations, and such repeated details are omitted herein. Compared to the electrostatic discharge protection circuit 10 in FIG. 1, an electrostatic discharge protection circuit 11 in FIG. 2 includes a Schottky diode SD and a diode D2. The Schottky diode SD has an anode coupled to an output pin P2 of the MCU 20, and a cathode coupled to the external circuit 30. The diode D2 has an anode coupled to the ground voltage GND, and a cathode together with the cathode of the Schottky diode SD coupled to the external circuit 30. It should be understood that, the diode D2 in FIG. 2 may similarly be, for example but not limited to, a Zener diode.

More specifically, the Schottky diode SD has a property of blocking a reverse voltage. Thus, when an electrostatic voltage (not shown) from the external circuit 30 is to enter the output pin P2 of the MCU 20 through the Schottky diode SD, the Schottky diode SD blocks the electrostatic voltage from entering, thus similarly achieving the effect of protecting the MCU 20. Similarly, because a Zener diode conventionally serving for protection purposes, i.e., the diode D2, is configured on the cathode of the Schottky diode SD, the diode D2 is still capable of similarly reducing the electrostatic voltage from the external circuit 30 during an electrostatic discharge test in the embodiment, and the specification of the diode D2 can be selected and determined according to the reverse voltage that can be blocked by the Schottky diode SD.

In other words, since a common Schottky diode is capable of blocking a reverse voltage of about 20 V or 30 V, this embodiment is capable of increasing the withstand voltage of originally 4 V or 6 V to 20 V, 30 V or an even higher voltage for the output pin P2, similarly increasing the voltage tolerance of the MCU 20 against electrostatic discharge, or equivalently enhancing the capability of the MCU 20 against electrostatic discharge. Similarly, to prevent an overly large current from damaging the diode D2 connected in series, the electrostatic discharge protection circuit 11 may further include a resistor R4, and the cathode of the diode D2 and the cathode of the Schottky diode SD are together coupled to the external circuit 30 through the resistor R4. Details of current limiting of the resistor R4 are the same as described above, and hence are omitted herein.

In conclusion, in the electrostatic discharge protection circuit provided by the embodiments of the present invention, an N-type MOSFET and a Schottky diode are respectively added on an input/output pin of the protection target connected to an external circuit and act as a solution for withstanding electrostatic discharge. Further, in the embodiments of the present invention, a Zener diode conventionally serving for protection purposes is configured on the gate of an N-type MOSFET and a cathode of a Schottky diode. Thus, during an electrostatic discharge test, the embodiments of the present invention can increase the withstand voltage of an input/output pin to 12 V or higher, which is equivalently enhancing the voltage tolerance of the protection target against electrostatic discharge. Further, in regard to selecting the specification of a Zener diode, by the embodiments of the present invention, it is easier to select a suitable Zener diode; that is, there is a wider range of selections for the specification of the Zener diode.

The above disclosures are embodiments of the present invention, and are not to be construed as limitations to the present invention.

What is claimed is:

1. An electrostatic discharge protection circuit, connected in series between a protection target and an external circuit, the electrostatic discharge protection circuit comprising:
an N-type field-effect transistor, having a drain coupled to an input pin of the protection target, a source coupled to a ground voltage, and a gate coupled to the external circuit; and
a diode, having an anode coupled to the ground voltage, and a cathode together with the gate of the N-type field-effect transistor coupled to the external circuit.

2. The electrostatic discharge protection circuit according to claim 1, further comprising:
a first resistor, through which the cathode of the diode and the gate of the N-type field-effect transistor are together coupled to the external circuit.

3. The electrostatic discharge protection circuit according to claim 2, wherein the N-type field-effect transistor is an N-type metal-oxide-semiconductor field-effect transistor (MOSFET); the input pin of the protection target and the drain of the N-type MOSFET are further together coupled to a reference voltage through a second resistor; when an electrostatic voltage from the external circuit causes a voltage difference between voltages at the gate and the source of the N-type MOSFET to exceed a threshold voltage, the N-type MOFSET is turned on such that a voltage at the input pin drops from a high level to a low level.

4. The electrostatic discharge protection circuit according to claim 3, wherein the diode is a Zener diode, and a specification of the Zener diode is selected and determined according to a gate withstand voltage of the N-type MOSFET.

5. The electrostatic discharge protection circuit according to claim 4, further comprising a third resistor connected in parallel to the Zener diode.

6. An electrostatic discharge protection circuit, connected in series between a protection target and an external circuit, the electrostatic discharge protection circuit comprising:
a Schottky diode, having an anode coupled to an output pin of the protection target, and a cathode coupled to the external circuit; and
a diode, having an anode coupled to a ground voltage, and a cathode together with the cathode of the Schottky diode coupled to the external circuit.

7. The electrostatic discharge protection circuit according to claim 6, wherein the diode is a Zener diode, and a specification of the Zener diode is selected and determined according to a reverse voltage that can be blocked by the Schottky diode.

8. The electrostatic discharge protection circuit according to claim 7, further comprising a resistor, through which the cathode of the Zener diode and the cathode of the Schottky diode are together coupled to the external circuit.
